(19) United States
(12) Patent Application Publication
(10) Pub. No.: US 2012/0267783 A1
(43) Pub. Date: Oct. 25, 2012

(54) STACKED-SUBSTRATE STRUCTURE

(75) Inventors: YU-CHENG LIU, TAICHUNG CITY (TW); CHIEN-NAN CHEN, KAOHSIUNG CITY (TW)

(73) Assignees: UNIVERSAL GLOBAL SCIENTIFIC INDUSTRIAL CO., LTD., Nantou County (TW); UNIVERSAL SCIENTIFIC INDUSTRIAL (SHANGHAI) CO., LTD., Shanghai (CN)

(21) Appl. No.: 13/151,334

(22) Filed: Jun. 2, 2011

(30) Foreign Application Priority Data
Apr. 20, 2011 (TW) 100113807

(51) Int. Cl. H01L 23/498

(52) U.S. Cl. 257/738; 257/E23.069

(57) ABSTRACT

The stacked-substrate structure includes a first substrate having a first die embedded therein, a second substrate having a second die embedded therein, a plurality of soldering elements, and a third die. The soldering elements are disposed between the first and the second substrates and connected to the first and the second substrates. The first and the second substrates are electrically connected via the soldering elements. The first substrate, the second substrate, and the soldering elements define an accommodating space. The third die is arranged in the accommodating space and is connected to one surface of the first substrate. The third die is electrically connected to the first and the second dies via the first substrate. Thus, the thickness of the stacked-substrate structure can be reduced, and the first and the second dies of the stacked-substrate structure can be test separately in different platforms.

### BACKGROUND OF THE INVENTION

1. Field of the Invention

The instant disclosure relates to a stacked structure; and more particularly, to a stacked-substrate structure.

2. Description of Related Art

With the rapid advancement in electronic products, the integrated circuit (IC) has been an indispensable product in this information age. countless integrated circuits have been utilized in note-book computers, cell phones, personal digital assistants, digital cameras, etc.

In terms of IC packaging, in order to achieve the ever-increasing demands for high speed and multi-tasking processing in modern electronic products, modern die package for the electronic product need to incorporate additional active units yet remain compact and low-profile in shape.

Thus, for the purpose of accommodating large number of the electronic units in a limited space, many package types of the integrated circuit can be used. For example, FIG. 1 shows a conventional stacked IC structure having an upper structure 1a and a lower structure 2a. The upper structure 1a has a substrate 11a, a plurality of dies 12a stacked on the substrate 11a, a plurality of metal wires 13a connected to the substrate 11a and the dies 12a, and a covering layer 14a covered the dies 12a and the metal wires 13a. The lower structure 2a has a substrate 21a and a processor 22a disposed on the substrate 21a.

However, reducing the thickness of the stacked structure is very difficulty, the dies 12a of the upper structure 1a can not be tested separately in different platforms, and the metal wires 13a are fractured easily.

### SUMMARY OF THE INVENTION

One object of the instant disclosure is to provide a stacked-substrate structure, wherein the dies are separately embedded in different substrates of the stacked-substrate structure, thereby reducing the thickness of the stacked-substrate structure and causing the dies can be test separately in different platforms.

The stacked-substrate structure in accordance with the instant disclosure includes a first substrate having a first die embedded therein, a second substrate having a second die embedded therein, a plurality of soldering elements, and a third die. The soldering elements are disposed between the first and the second substrates and connected to the first and the second substrates. The first and the second substrates are electrically connected via the soldering elements. The first substrate, the second substrate, and the soldering elements define an accommodating space. The third die is arranged in the accommodating space and is connected to one surface of the first substrate. The third die is electrically connected to the first and the second dies via the first substrate.

Based on the above stacked-substrate structure, the thickness of the stacked-substrate structure can be reduced, and the first and the second dies of the stacked-substrate structure can be test separately in different platforms. In addition, the instant disclosure can avoid the problems generated by the metal wires.

### BRIEF DESCRIPTION OF THE DRAWINGS

FIG. 1 is a sectional view illustrating the stacked structure of the related art.

FIG. 2 is a schematic view illustrating the stacked-substrate structure of the instant disclosure.

FIG. 3 is an enlarged view of FIG. 2 of the instant disclosure.

### DETAILED DESCRIPTION OF THE PREFERRED EMBODIMENTS

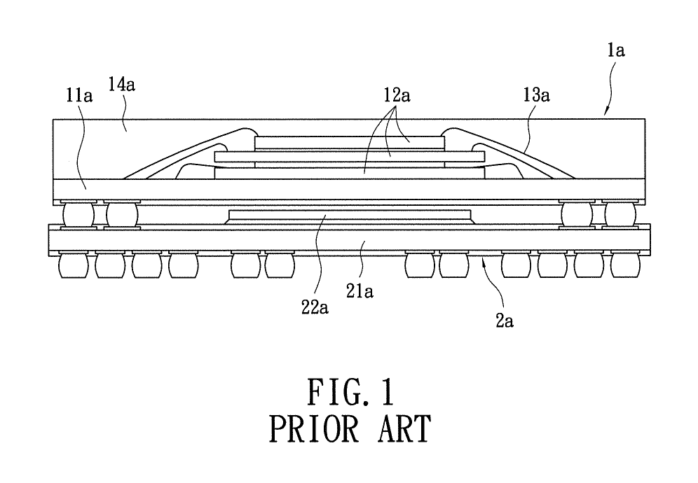

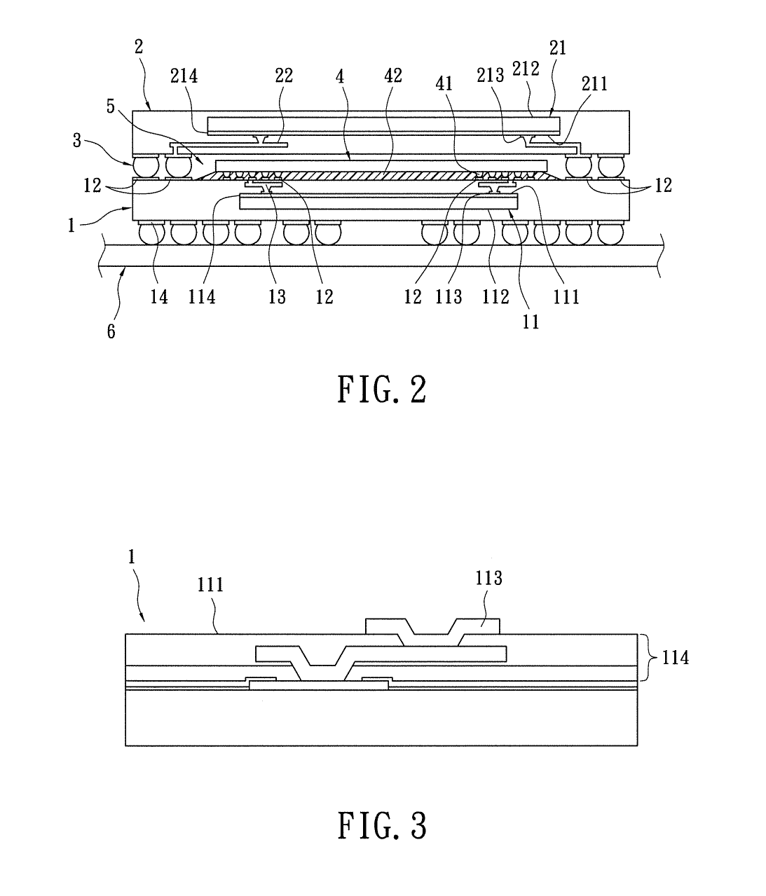

Please refer to FIG. 2 and FIG. 3, which show the embodiment of the instant disclosure, wherein FIG. 1 shows the schematic of the instant disclosure, FIG. 3 shows the enlarged view of the instant disclosure.

Please refer to FIG. 2, which is a stacked-substrate structure. The stacked-substrate structure includes a first substrate 1 having a first die 11 embedded therein, a second substrate 2 having a second die 21 embedded therein, a plurality of soldering elements 3 disposed between the first substrate 1 and the second substrate 2 and connected to the first substrate 1 and the second substrate 2, and a third die 4 disposed between the first substrate 1 and the second substrate 2. The first substrate 1 and the second substrate 2 are electrically connected via the soldering elements 3. The first substrate 1, the second substrate 2, and the soldering elements 3 define an accommodating space 5. The third die 4 is arranged in the accommodating space 5, and the third die 4 is connected to one surface of the first substrate 1. The third die 4 is electrically connected to the first die 11 and the second die 21 via the first substrate 1.

Thus, before welding the first substrate 1 and the second substrate 2 by the soldering elements 3, the first substrate 1 and the second substrate 2 can be disposed on different platforms, so that the first die 11 and the second die 21 can be separately tested. In addition, because the first die 11 and the second die 21 are respectively embedded in the first substrate 1 and the second substrate 2, which reinforcing the structure strength of the first substrate 1 and the second substrate 2 and improving the warping condition of the first substrate 1 and the second substrate 2.

The first substrate 1 has a pattern layer 12 formed on the surface thereof, wherein the surface of the first substrate 1 is adjacent to the second substrate 2. The third die 4 is connected to the soldering elements 3 via the pattern layer 12. The first substrate 1 and the second substrate 2 each has a conducting circuit 13, 22 formed therein.

The conducting circuit 13 of the first substrate 1 is electrically connected to the first die 11 and the pattern layer 12. The first die 11 and the third die 4 are electrically connected via the conducting circuit 13 of the first substrate 1 and the pattern layer 12. The conducting circuit 22 of the second substrate 2 is electrically connected to the second die 21 and the soldering elements 3. The second die 21 and the third die 4 are electrically connected via the conducting circuit 22 of the second substrate 2, soldering elements 3, and the pattern layer 12. The first substrate 1 has a plurality of solder pads 14 formed on the opposite surface thereof, the solder pads are used for welding to a circuit board 6, wherein the surface and the other surface of the first substrate 1 are formed oppositely.

Compared with the conventional IC structure, such as shown in FIG. 1, the metal wires of the related art are replaced with the conducting circuits 13, 22 of the first substrate 1 and the second substrate 2. Thus, the instant disclosure can avoid the inherent reliability problems of the wire bonding process.

Meanwhile, the first die 11 and the second die 21 each has an active surface 111, 211 and a non-active surface 112, 212 formed oppositely, the active surfaces 111, 211 of the first die 11 and the second die 21 are electrically connected to the conducting circuits 13, 22 respectively, and then electrically connected to the third die 4. More specifically, the first die 11 and the second die 21 each has a plurality of contacts 113, 213 formed on the active surface 111, 211 thereof. The contacts 113, 213 of the first die 11 and the second die 21 are respectively electrically connected to the conducting circuits 13, 22 of the first substrate 1 and the second substrate 2.

The active surfaces 111, 211 of the first die 11 and the second die 21 are faced to each other, thereby reducing the electrical path of the first die 11 and the second die 21 to the third die 4 and achieving better transmission effect. In addition, the present embodiment is disclosed the active surfaces 111, 211 of the first die 11 and the second die 21 are faced to each other. However, in use, the active surfaces 111, 211 of the first die 11 and the second die 21 can be disposed with facing to the opposite directions or the same direction.

Please refer to FIG. 3, in order to make the first die 11 and the second die 21 can be applied on different modules, the first die 11 and the second die 21 each has a redistribution layer 114, 214. The active surfaces 111, 211 and the contacts 113, 213 of the first die 11 and the second die 21 are respectively formed on the outside of the redistribution layers 114, 214 of the first die 11 and the second die 21. Therefore, the original circuit design of the first die 11 and the second die 21 can be changed by the redistribution layers 114, 214, so that the first die 11 and the second die 21 can be applied on different modules.

The soldering elements 3 are disposed between the first substrate 1 and the second substrate 2, and the soldering elements 3 are electrically connected to the first substrate 1 and the second substrate 2. In this embodiment, the soldering elements 3 are solder balls but not limited thereto.

There are a plurality of micro bumps 41 and a dielectric layer 42 disposed between the third die 4 and the first substrate 1, wherein the micro bumps 41 are connected to the third die 4 and the first substrate 1. In more detail, the micro bumps 41 are connected to the third die 4 and the pattern layer 12 of the first substrate 1, and the micro bumps 41 are covered in the dielectric layer 42. The dielectric layer 42 can be die bound glue with thin film type or the other suitable dielectric material.

In addition, the thickness of the stacked-substrate structure is about 1.32 mm to 1.52 mm, wherein the suitable thickness is 1.42 mm. However, in use, the thickness of the stacked-substrate structure is not limited thereto.

Furthermore, the instant stacked-substrate structure may be applied to field of memory design. For example, the first die 11 and the second die 12 may be memory devices, and the third die 4 may be a processor.

The first die 11 can be a non-volatile memory. That is, the information stored in the first die 11 does not disappear when the memory device is not powered, while the information stored in the first die 11 can be read as power is resupplied. The main types of the non-volatile memory includes: Read-only memory (ROM), Programmable read-only memory (PROM), Erasable programmable read only memory (EPROM), Electrically erasable programmable read only memory (EEPROM), and Flash memory. In this embodiment, the first die 11 is NAND flash memory but not limited thereto.

The second die 21 can also be a volatile memory. That is, the information stored in the second die 21 will disappear as power does not be supplied. The main types of the volatile memory includes: Random access memory (RAM), Dynamic random access memory (DRAM), and Static random access memory (SRAM). In this embodiment, the first die 11 is NAND memory but not limited thereto.

Various embedding techniques may be adapted to incorporate the first die 11 and the second die 21 into the first substrate 1 and the second substrate 2, respectively. The embedded manner in this embodiment (not shown) is described as follows but not limited thereto.

The substrate has a plurality of conducting layers and a plurality of pre-impregnated composite materials (pre-pregs) disposed staggered with the conducting layers, wherein the conducting layers can be copper foils and the prepregs can be FR4 or FR5. Namely, between each two conducting layers has one prepreg disposed in thereof.

The die is embedded in one of the prepregs and connected to the conducting layer, wherein the conducting layer can be connected to the active surface or the non-active surface of the die.

Finally, practicing laser drill and electroplating and forming the pattern layer or the solder pads on the outside of the substrate, goes even further electrically connecting the die to the pattern layer or the solder pads.

Compared to related art, the thickness of the stacked-substrate structure is about 1.32 mm to 1.52 mm, wherein a typical preferable thickness is 1.42 mm.

In addition, the first substrate 1 and the second substrate 2 can be disposed on different platforms, so that the first die 11 and the second die 21 can be separately tested, which reinforcing the structure strength of the first substrate 1 and the second substrate 2 and improving the warping condition of the first substrate 1 and the second substrate 2.

Furthermore, the instant disclosure can be used for shorting the electrical path of the first die 11 and the second die 21 to the third die 4 and achieving better transmission effect. The instant disclosure can avoid the problems generated by the metal wires.

The description above only illustrates specific embodiments and examples of the instant disclosure. The instant disclosure should therefore cover various modifications and variations made to the herein-described structure and operations of the instant disclosure, provided they fall within the scope of the instant disclosure as defined in the following appended claims.

What is claimed is:

1. A stacked-substrate structure, comprising:
a first substrate having a first die embedded therein;
a second substrate having a second die embedded therein;
a plurality of soldering elements having predetermined thickness disposed between the first and the second substrates for establishing electrical connection there-between, the region encircled by the soldering elements between the first substrate and the second substrate defines an accommodating space; and
a third die disposed on one surface of the first substrate and arranged in the accommodating space,
wherein the third die is electrically connected to the first and the second dies via the first substrate.

2. The stacked-substrate structure as claimed in claim 1, wherein the first substrate has a conducting circuit formed therein, wherein the conducting circuit is electrically connected to the first and the third dies.

3. The stacked-substrate structure as claimed in claim 1, wherein the first and the second dies each has an active surface and a non-active surface formed on the opposite surfaces thereof, wherein the active surfaces of the first and the second dies are arranged facing each other and electrically connected to the third die.

4. The stacked-substrate structure as claimed in claim 3, wherein each active surface of the first and the second dies has a plurality of contacts formed thereon.

5. The stacked-substrate structure as claimed in claim 4, wherein the first and the second dies each has a redistribution layer, wherein the active surfaces of the first and the second dies are respectively formed on the outside of the redistribution layers thereof.

6. The stacked-substrate structure as claimed in claim 1, wherein the first substrate has a plurality of solder pads formed on the opposite surface thereof for electrically coupling to a circuit board.

7. The stacked-substrate structure as claimed in claim 1, wherein the first and the second dies are memories, wherein the third die is a processor, the soldering elements are solder balls.

8. The stacked-substrate structure as claimed in claim 7, wherein the first die is a non-volatile memory, wherein the second die is a volatile memory.

9. The stacked-substrate structure as claimed in claim 7, wherein the first die is a NAND flash memory, the second die is a LPDDR memory.

10. The stacked-substrate structure as claimed in claim 1, wherein there are a plurality of micro bumps and a dielectric layer disposed between the third die and the first substrate, wherein the micro bumps are embedded in the dielectric layer for electrically connecting the third die and the first substrate.
